(19) United States
(12) Patent Application Publication
(10) Pub. No.: US 2012/0241803 A1
(43) Pub. Date: Sep. 27, 2012

(54) SEMICONDUCTOR LIGHT EMITTING DEVICE AND METHOD FOR MANUFACTURING SAME

(75) Inventor: Yoshiyuki KINUGAWA, Fukuoka-ken (JP)

(73) Assignee: Kabushiki Kaisha Toshiba, Tokyo (JP)

(21) Appl. No.: 13/419,051

(22) Filed: Mar. 13, 2012

(30) Foreign Application Priority Data
Mar. 23, 2011 (JP) 2011-064908

(51) Int. Cl. H01L 33/42

(52) U.S. Cl. 257/99; 438/22; 257/E33.064

(57) ABSTRACT

According to an embodiment, a semiconductor light emitting device includes a stacked body, a transparent electrode layer, a first electrode and a second electrode. The stacked body includes a first semiconductor layer, a second semiconductor layer, and a light emitting layer provided between the first semiconductor layer and the second semiconductor layer. The transparent electrode layer is provided on a surface of the second semiconductor layer and transmitting light emitted from the light emitting layer. The first electrode is electrically connected to the transparent electrode layer; and the second electrode is electrically connected to the first semiconductor layer. A region is provided along an edge of the transparent electrode layer with a part of the transparent electrode layer having a thickness smaller on the edge side than a thickness on a central side.

### CROSS-REFERENCE TO RELATED APPLICATIONS

This application is based upon and claims the benefit of priority from Japanese Patent Application No. 2011-064908, filed on Mar. 23, 2011; the entire contents of which are incorporated herein by reference.

### FIELD

Embodiments are generally related to a semiconductor light emitting device and a method for manufacturing the same.

### BACKGROUND

Semiconductor light emitting devices are expected as not only display use, but also light sources with low power consumption substituted for bulb light sources such as bulbs or fluorescent lamps. Then, for example, for the purpose of replacing a bulb light source, or the like, the output of semiconductor light emitting devices is desired to increase.

For example, in light-emitting diodes (LEDs), by evenly injecting current into the entire light emitting layer, it is possible to improve the light emission efficiency. Furthermore, by improving the light extraction efficiency from semiconductor crystals, it is possible to increase the output. Therefore, an electrode pattern for equalizing the current injected into the light emitting layer, a technique for forming a transparent electrode on the entire light emitting face, and the like have been proposed. However, only these techniques cannot satisfy the requirement of increasing the output. There is a need for a semiconductor light emitting device and method for manufacturing the same, which realize further increase in the output at a low cost.

### BRIEF DESCRIPTION OF THE DRAWINGS

FIGS. 1A and 1B are schematic views illustrating a structure of a semiconductor light emitting device according to a first embodiment;

FIGS. 2A to 4 are schematic cross-sectional views illustrating manufacturing processes of the semiconductor device according to the first embodiment;

FIGS. 5A and 5B are schematic views illustrating examples of light extraction in the semiconductor light emitting devices according to the first embodiment;

FIGS. 6A and 6B are schematic views illustrating examples of current injection in the semiconductor light emitting devices according to the first embodiment;

FIGS. 7A and 7C are schematic views illustrating other examples of current injection in the semiconductor light emitting devices according to the first embodiment;

FIG. 8 is a graph showing examples of the light output of the semiconductor light emitting device according to the first embodiment;

FIG. 9 is a graph showing another examples of the light output of the semiconductor light emitting device according to the first embodiment;

FIG. 10 is a schematic cross-sectional view illustrating a manufacturing process of the semiconductor device according to the first embodiment;

FIGS. 11A and 11B are schematic cross-sectional views illustrating manufacturing processes of a semiconductor light emitting device according to a second embodiment;

FIGS. 12A and 12B are schematic cross-sectional views illustrating manufacturing processes of a semiconductor light emitting device according to a third embodiment; and

FIGS. 13A and 13B are schematic cross-sectional views illustrating manufacturing processes of a semiconductor light emitting device according to a fourth embodiment.

### DETAILED DESCRIPTION

According to an embodiment, a semiconductor light emitting device includes a stacked body, a transparent electrode layer, a first electrode and a second electrode. The stacked body includes a first semiconductor layer of a first conductivity type, a second semiconductor layer of a second conductivity type, and a light emitting layer provided between the first semiconductor layer and the second semiconductor layer. The transparent electrode layer is provided on a surface of the second semiconductor layer and transmitting light emitted from the light emitting layer. The first electrode is electrically connected to the transparent electrode layer; and the second electrode is electrically connected to the first semiconductor layer. A region is provided along an edge of the transparent electrode layer with a part of the transparent electrode layer having a thickness smaller on the edge side than a thickness on a central side.

Embodiments of the invention will now be described with reference to the drawings. Also, in the following embodiments, the identical parts in the drawings are marked with like reference numerals, detailed descriptions thereof are omitted as appropriate, and the different parts are described. Furthermore, although a first conductivity type is described as an n-type and a second conductivity type is described as a p-type, the first conductivity type may be a p-type and the second conductivity type may be an n-type.

### First Embodiment

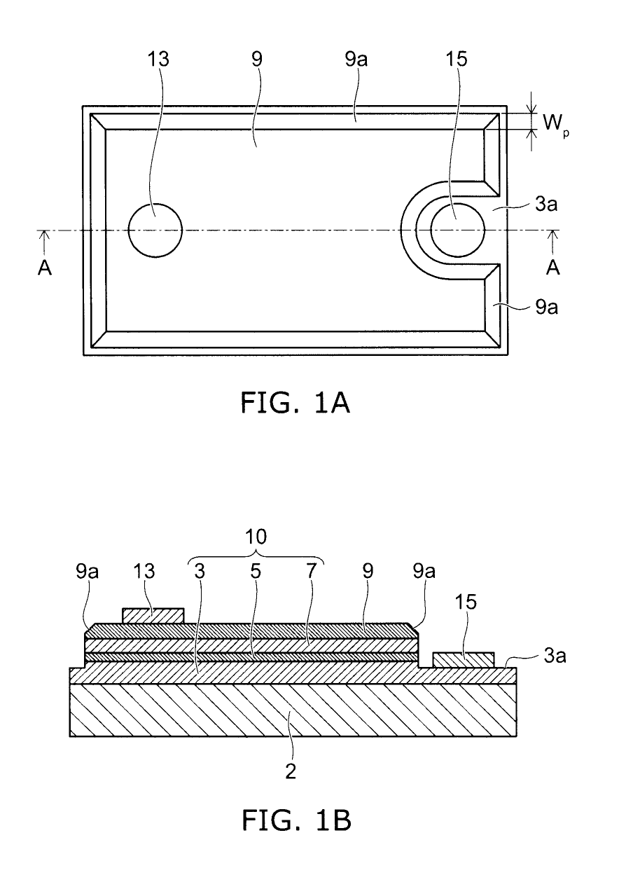

FIGS. 1A and 1B are schematic views showing a structure of a semiconductor light emitting device 100 according to the first embodiment. FIG. 1A is a plan view showing a light emitting face, and FIG. 1B shows the structure of the cross section taken along the line A-A in FIG. 1A.

The semiconductor light emitting device 100 is an LED including, for example, a GaN-based nitride semiconductor as material. As shown in FIG. 1A, the semiconductor light emitting device 100 has an external shape of a rectangular, and includes, at its ends, a p-electrode 13 that is a first electrode and an n-electrode 15 that is a second electrode.

Then, as shown in FIG. 1B, the semiconductor light emitting device 100 includes a stacked body 10 having an n-type GaN layer 3 that is a first semiconductor layer, having a light emitting layer 5, and having a p-type GaN layer 7 that is a second semiconductor layer, provided on a sapphire substrate 2, for example. The light emitting layer 5 is provided between the n-type GaN layer 3 and the p-type GaN layer 7, and includes a quantum well configured by an InGaN well layer and a GaN barrier layer, for example.

A transparent electrode layer 9 is provided on a surface of the p-type GaN layer 7. The transparent electrode layer 9 has conductivity with low resistance, and spreads current on the entire face of the p-type GaN layer 7 to inject it into the light emitting layer 5. Furthermore, a material transparent to light emission is used for the transparent electrode layer 9 in order to extract the emitted light of the light emitting layer 5 to outside. For example, ITO (Indium Tin Oxide) that is a conductive oxide film can be used for the transparent electrode layer 9.

A p-electrode 13 is provided on a surface of the transparent electrode layer 9. The p-electrode 13 is a metal film in which a nickel (Ni) and a gold (Au), for example, are stacked in sequence, and is provided to be electrically connected to the transparent electrode layer 9.

Furthermore, the n-electrode 15 is provided on a surface 3a of the n-type GaN layer 3 exposed by selectively removing the transparent electrode layer 9, the p-type GaN layer 7, and the light emitting layer 5. The p-electrode 15 is a metal film in which a titanium (Ti) and an aluminum (Al), for example, are stacked in sequence, and is electrically connected to the n-type GaN layer 3.

The semiconductor light emitting device 100 according to the embodiment, as shown in FIG. 1A, has a region 9a along the edge of the transparent electrode layer 9. The region 9a is provided so that the thickness of the transparent electrode layer 9 becomes smaller on the edge side than on the central side. For example, as shown in FIG. 1B, the region 9a can be formed in a tapered shape that becomes thinner from the central side toward the edge.

Furthermore, the edge of the transparent electrode layer 9 is in contact with a side face 10a. The side face 10a is provided by continuously etching the transparent electrode layer 9, the p-type GaN layer 7, and the light emitting layer 5, in the direction from the surface of the transparent electrode layer 9 to the n-type GaN layer 3. That is, as shown in FIG. 1B, the edge of the transparent electrode layer 9 coincides with the edge of the p-type GaN layer 7. Then, not only the case where the edge of the transparent electrode layer 9 coincides with the edge of the p-type GaN layer 7 in a strict sense, but also the case is included, where the edge of the transparent electrode layer 9 roughly coincides with the edge of the p-type GaN layer 7. For example, there may be a step comparable to a step generated due to the difference between an etching rate in the lateral direction of the transparent electrode layer 9 and an etching rate in the lateral direction of the p-type GaN layer 7.

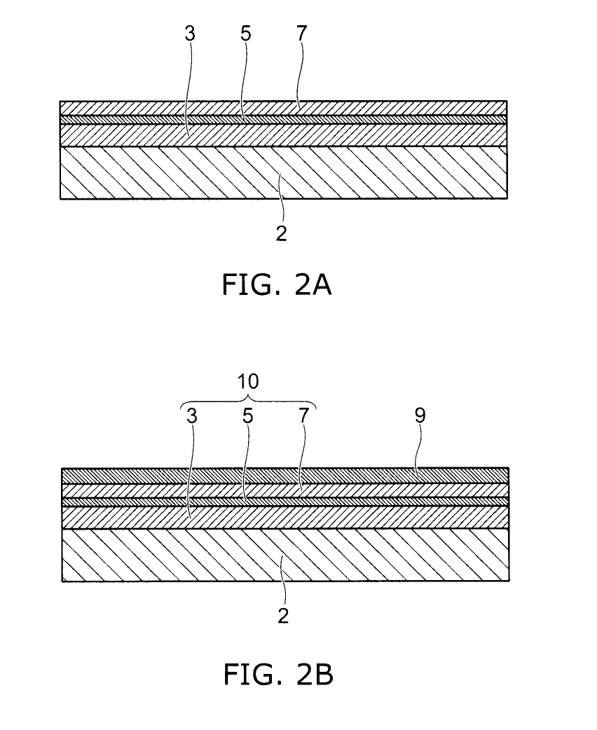

Next, with reference to FIGS. 2A to 4, manufacturing processes of the semiconductor light emitting device 100 will be described. FIGS. 2A to 4 are cross-sectional views schematically showing a part of wafers in each of the manufacturing processes.

First, as shown in FIG. 2A, the n-type GaN layer 3, the light emitting layer 5, and the p-type GaN layer 7 are formed in sequence on the sapphire substrate 2. These nitride semiconductor layers can be formed by using a MOCVD (Metal Organic Chemical Vapor Deposition) method, for example.

Next, as shown in FIG. 2B, the transparent electrode layer 9 is provided on the surface of the p-type GaN layer 7. The transparent electrode layer 9 is a conductive film with low resistance. A material that transmits the emitted light emitted from the light emitting layer 5 is used for the transparent electrode layer 9. For example, a conductive oxide film such as ITO or ZnO may be used for the transparent electrode layer 9, which can be formed by using a sputtering method or evaporation method.

The thickness of the transparent electrode layer 9 is determined in view of its sheet resistance and transmittance. For example, if the transparent electrode layer 9 is thickened, although the sheet resistance becomes low, the transmittance of emitted light decreases. In contrast, if the transparent electrode layer 9 is thinly formed, although the transmittance becomes high, the sheet resistance becomes high. For example, in the case of ITO, the transparent electrode layer 9 may be provided so as to have a thickness of about 250 nm.

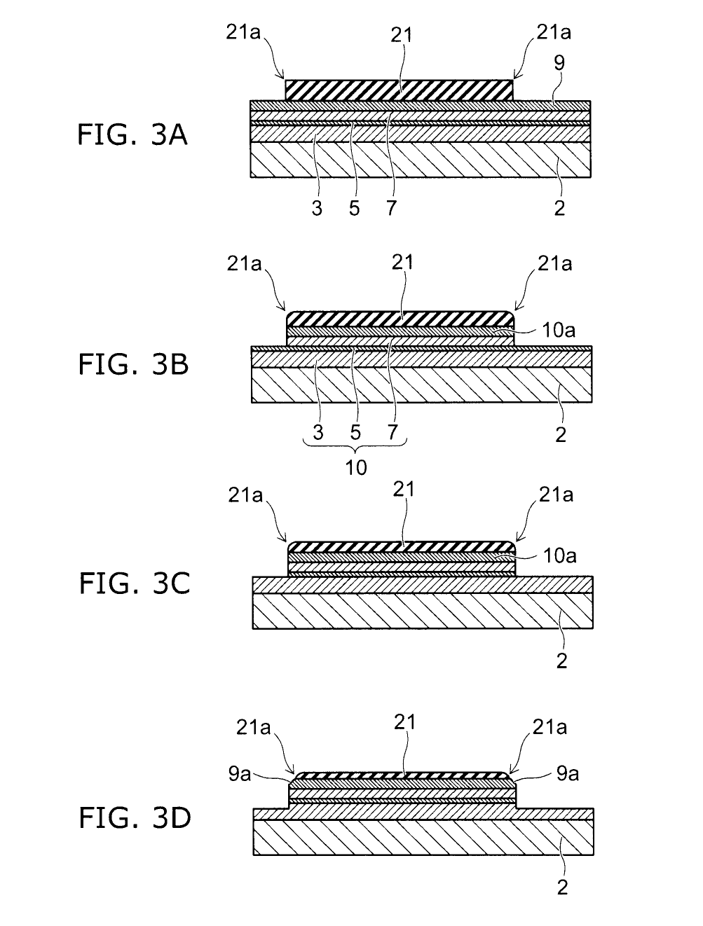

Next, as shown in FIG. 3A, an etching mask 21 is formed to cover a part of the transparent electrode layer 9. A silicon oxide film (SiO₂ film), for example, is used for the etching mask 21. Subsequently, the transparent electrode layer 9, the p-type GaN layer 7, and the light emitting layer 5, are continuously etched by using, for example, an RIE (Reactive Ion Etching) method. The etching proceeds in the direction from the surface of the transparent electrode layer 9 to the n-type GaN layer 3.

FIGS. 3B to 3D shows schematically a process of etching. Etching gas may include Chlorine (Cl₂). An etching condition is used in which etching in the vertical direction (the direction from the transparent electrode layer 9 toward the n-type GaN layer 3) is dominant.

As shown in FIG. 3B, in an initial stage of etching, for example, the transparent electrode layer 9 and the p-type GaN layer 7 are selectively etched using the etching mask 21, forming the vertical etched face 10a. At the same time, the etching mask 21 also is etched to become thin. Then, the etching of the etching mask 21 proceeds in an edge 21a and the etching mask 21 becomes thinner in the direction from the center to the edge 21a.

Furthermore, as the etching proceeds, as shown in FIG. 3C, the thickness in the edge 21a of the etching mask 21 becomes zero. Then, in the subsequent etching, as shown in FIG. 3D, the edge 21a of the etching mask 21 retreats to the central side, and the end part of the transparent electrode layer 9 is gradually etched. Then, the shape of the etching mask 21 is transferred at the edge to the transparent electrode layer 9, and the thickness of the transparent electrode layer 9 becomes smaller from the center side toward the edge.

As a result, the surface of the n-type GaN layer 3 can be exposed in the bottom of the etched region, and at the same time, the region 9a is formed along the edge of the transparent electrode layer 9. In other words, the thickness of the etching mask 21 is adjusted so that the region 9a is formed in the end of the transparent electrode layer 9, while the transparent electrode layer 9, the p-type GaN layer 7, and the light emitting layer 5 are removed, and the surface 3a of the n-type GaN layer 3 is exposed.

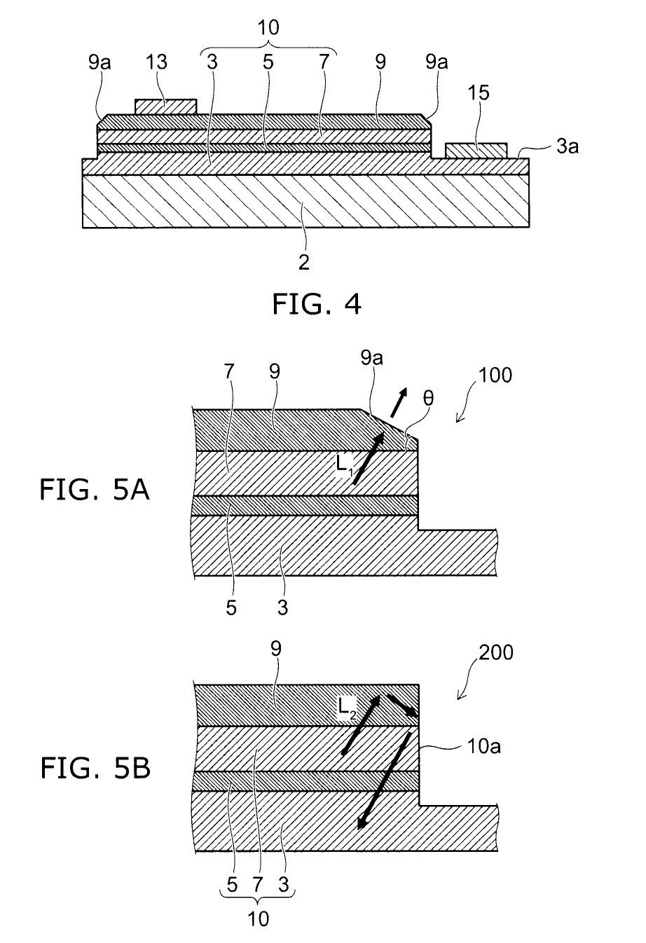

Subsequently, the etching mask 21 is removed by wet etching, for example. Then, as shown in FIG. 4, the p-electrode 13 is formed on the surface of the transparent electrode layer 9, and the n-electrode layer 15 is formed on the surface 3a of the n-type GaN layer 3. The p-electrode 13 can be formed by stacking Ni and Au in sequence on the surface of the transparent electrode layer 9 using, for example, a vacuum evaporation method, and by patterning them to the predetermined shape. The n-electrode 15 can be formed by stacking Ti and Al in sequence using, for example, a sputtering method or evaporation method, and by patterning them to the predetermined shape.

The semiconductor light emitting device 100 is completed by the above-described manufacturing processes. Furthermore, individual semiconductor light emitting devices 100 are cut into a chip from a wafer by using a dicer, for example, after the back face of the sapphire substrate 2 is ground to be thin.

Next, the function of the semiconductor light emitting devices according to the embodiment will be described with reference to FIGS. 5A to 7C. FIGS. 5A to 7C are schematic views showing partial cross sections of the semiconductor light emitting devices 100, 110, 120, 200 and 300.

FIG. 5A shows a part of the semiconductor device 100 according to the embodiment, and FIGS. 5B shows a part of the semiconductor light emitting device 200 according to comparative examples.

For example, in the semiconductor light emitting device 100 as shown in FIG. 5A, an emitted light L₁ emitted from the light emitting layer 5 and propagated toward the edge of the transparent electrode layer 9 transmits the region 9a to be emitted to outside.

In contrast to this, in the semiconductor light emitting device 200 as shown in FIG. 5B, the region 9a in the end of the transparent electrode layer 9 is not provided. Then, an emitted light L₂ incident on the surface of the transparent electrode layer 9 at an angle larger than the critical angle is totally reflected from the surface of the transparent electrode layer 9 and the etched face 10a. The light L₂ attenuates in the stacked body 10, while repeating reflection. That is, a part of the emitted light propagated toward the end of the transparent electrode layer 9 cannot be extracted to outside.

In this manner, in the semiconductor light emitting device 100 according to the embodiment, a region 9a along the edge of the transparent electrode layer 9 is provided, and the total reflection of the emitted light emitted from the light emitting layer 5 is reduced, thereby improving light extraction efficiency.

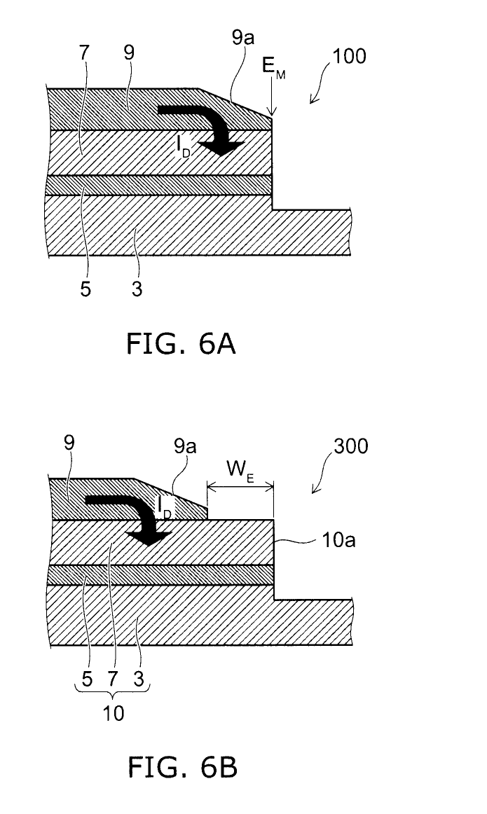

FIGS. 6A and 6B are schematic views showing examples of current injection in the semiconductor light emitting devices 100 and 300. FIG. 6A shows the semiconductor light emitting device 100 according to the embodiment. FIG. 6B shows the semiconductor light emitting device 300 according to the comparative example.

In the semiconductor light emitting device 100 as shown in FIG. 6A, the edge E_{M} of the transparent electrode layer 9 is included in the etched face 10a. Then, the edge E_{M} of the transparent electrode layer 9, the edge of the p-type GaN layer 7, and the edge of the light emitting layer 5 coincides with one another, and a drive current I_{D} spread by the transparent electrode layer 9 can be injected to the end part of the light emitting layer 5.

In contrast, in the semiconductor light emitting device 300 as shown in FIG. 6B, the edge of the transparent electrode layer 9 is formed in a state, where the edge of the transparent electrode layer 9 retreats by only W_{E} inside the stacked body 10 from the edges of the p-type GaN layer 7 and the light emitting layer 5. Therefore, when the drive current I_{D} is spread into the p-type GaN layer 7 by the transparent electrode layer 9, the current injected into the end part of the light emitting layer 5 is small, and the light emission intensity becomes lower. That is, in the semiconductor light emitting device 300, the light emission intensity lowers in the end part of the light emitting layer 5, and the substantial light emission area becomes small. On this account, the light output of the semiconductor light emitting device 300 is lower than the light output of the semiconductor light emitting device 100.

In a manufacturing process of the semiconductor light emitting device 300, the transparent electrode layer 9, the p-type GaN layer 7, and the light emitting layer 5 are not continuously etched, and are processed in different steps. That is, after the step in which the transparent electrode layer 9 is patterned, the etching of the p-type GaN layer 7 and the light emitting layer 5 is carried out in the subsequent step. The etching mask 21 shown in FIG. 3A covers the patterned transparent electrode layer 9. Therefore, the edge of the transparent electrode layer 9 is formed in the state in which the edge of the transparent electrode layer 9 retreats by only W_{E} inside the stacked body 10 from the edges of the p-type GaN layer 7 and the light emitting layer 5.

In contrast, the transparent electrode layer 9, the p-type GaN layer 7, and the light emitting layer 5 are continuously etched in the semiconductor light emitting device 100 according to the embodiment, and thus the edge E_{M} of the transparent electrode layer 9 coincides with the edge of the p-type GaN layer 7 and the edge of the light emitting layer 5. Hence, it becomes possible to inject the current into the edge of the light emitting region 5 and to spread the substantial light emitting area in the light emitting layer 5, whereby the light output is improved.

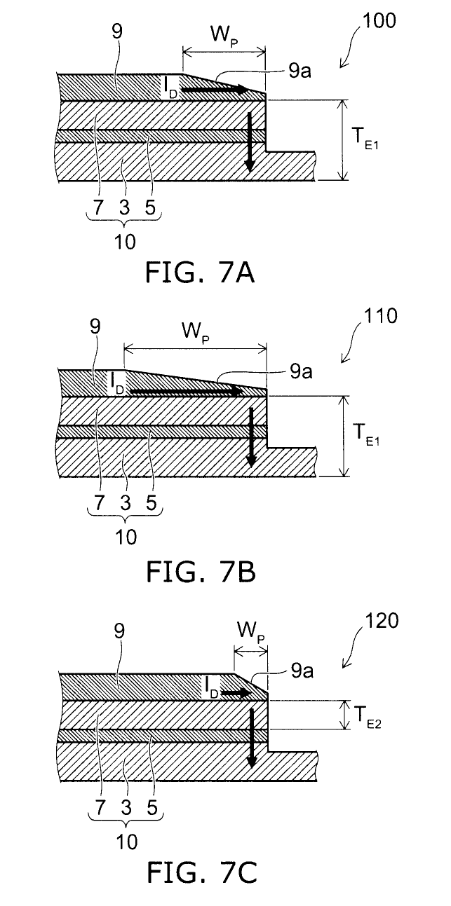

FIGS. 7A to 7C are schematic views showing examples of current injection in the semiconductor light emitting devices 100, 110 and 120. In the semiconductor light emitting devices 100 to 120, each width W_{P} (see FIG. 1A) of the region 9a is different. W_{P} is the width of the region 9a between the central side and the edge in the direction (lateral direction) along the surface of the p-type GaN layer 7.

In the region 9a, the thickness of the transparent electrode layer 9 becomes smaller on the edge side than on the central side, and thus the resistance of the transparent electrode layer 9 becomes high on the edge side, thereby limiting the spread of the driving current I_{D} to the edge side. As decreasing the driving current I_{D} that is injected into the end part of the light emitting layer 5, the light emission intensity decreases in the end part. Therefore, to increase the substantial light emitting area in the light emitting layer 5, it is advantageous to narrow the width W_{P} of the region 9a.

In contrast, in view of the light extraction efficiency described with reference to FIG. 5A, it is advantageous to increase the width W_{P} of the region 9a in order to reduce the totally reflected component of the emitted light. That is, the width W_{P} of the region 9a is determined in view of the substantial light emitting area and the light extraction efficiency.

As one criterion, it is possible to take into account a thickness T_{E1} of the stacked body 10 in the stacking direction. For example, with respect to the drive current I_{D} injected into the end part of the light emitting layer 5, W_{P} can be regarded as the length of the current pathway in the lateral direction, and T_{E1} can be regarded as the length of the current pathway in the stacking direction. Then, the case where W_{P} is wider than T_{E1} and the case where W_{P} is narrower than T_{E1} are different from each other in the effect of the resistance of the region 9a, on the current injected into the end part of the light emitting layer 5.

For example, in the semiconductor light emitting device 100 as shown in FIG. 7A, W_{P} is provided so as to be smaller than the thickness T_{E1}, and the current pathway in the stacking direction becomes longer than the current pathway in the lateral direction. Therefore, the effect of the resistance of the transparent electrode layer 9, on the spread in the lateral direction of the drive current I_{D} is relieved, and then the decrease in light emission intensity can be suppressed in the end part of the light emitting layer 5.

In contrast, in the semiconductor light emitting device 110 as shown in FIG. 7B, W_{P} is provided larger than T_{E1}, and the current pathway in the lateral direction becomes longer than the current pathway in the stacking direction. Therefore, the resistance of the region 9a limits the spread of the drive current I_{D} in the lateral direction, decreasing the current injection into the end part of the light emitting layer 5. Then, even if the improvement of light extraction efficiency is expected as an effect of increasing W_{P}, the decrease in light emission intensity in the end part of the light emitting layer 5 is more significant, and the improvement of the light output is limited.

That is, in the semiconductor light emitting device 100, W_{P} is preferably made narrower than T_{E1}, and thus the decrease in light emission intensity can be suppressed in the end part of the light emitting layer 5. Then, in the range in which W_{P} is smaller than T_{E1}, W_{P} is optimized, and thereby it is possible to increase the light extraction efficiency and to improve the light output.

Furthermore, as shown in the semiconductor light emitting device 120 as shown in FIG. 7C, W_{P} may be formed smaller than a thickness T_{E2} of the semiconductor layer (here, p-type GaN layer 7) stacked on the light emitting layer 5. Because of this, the spread in the lateral direction, of the drive current I_{D} is maintained, the decrease in light emission intensity is further suppressed in the end part of the light emitting layer 5, and then the light output can be improved.

Here, it should be noted that when the thickness of the transparent electrode layer 9 changes continuously between the region 9a and the central part that is not etched, of the transparent electrode layer 9, the position of the boundary might not be specified. Therefore, it is preferable to define the width W_{P} of the region 9a as the distance from the point where the thickness of the transparent electrode layer 9 is 10% smaller than the thickness of the central part that is not etched, to the edge of the transparent electrode layer 9, for example.

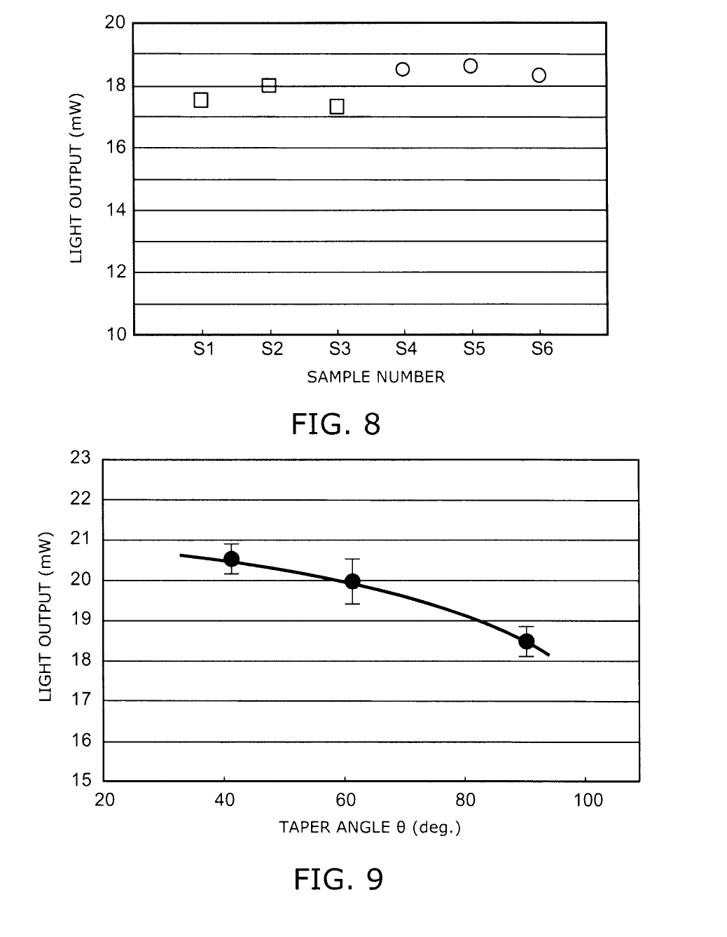

FIG. 8 is a graph showing examples of the light output of the semiconductor light emitting device 100 according to the embodiment. The horizontal axis represents the sample number, and the vertical axis represents the light output. Each of the semiconductor light emitting devices as shown by sample numbers S1 to S3 has a structure in which the region 9a is not formed in the edge of the transparent electrode layer 9, and the edge of the transparent electrode layer 9 retreats inside the stacked body 10 from the edges of the p-type GaN layer 7. In contrast, the light output of sample numbers S4 to S6 is data on the semiconductor light emitting devices 100, and it can be seen that the light output is about 18% higher than the light output of S1 to S3.

FIG. 9 is a graph showing another example of the light output of the semiconductor light emitting device 100. The horizontal axis represents the taper angle (see FIG. 5A) of the tapered region 9a formed in the edge of the transparent electrode layer 9, and the vertical axis represents the light output. The chip size of the semiconductor light emitting device 100 is 350 μm in long side length and 300 μm in short side length.

As shown in FIG. 9, it can be seen that the light output is improved, as θ becomes smaller from 60° to 40°, in comparison with the light output in the case where the taper angle θ is 90° corresponding to a structure in which the region 9a is not formed. This shows that the light extraction efficiency is improved by increasing the width W_{P} of the region 9a. The thickness of the stacked body 10 is about 6 μm, and the thickness of the transparent electrode layer 9 (ITO) is 250 nm. T_{E2} and W_{P} are in the range of T_{E2}>W_{P}.

In this manner, in the semiconductor light emitting device 100 according to the embodiment, the thickness of the transparent electrode layer 9 is provided so as to become smaller from the central side to the edge side, in the region 9a along the edge of the transparent electrode layer 9. Therefore, it is possible to increase the light extraction efficiency and to improve the light output. Furthermore, by continuously etching the electrode layer 9, the p-type GaN layer 7, and the light emitting layer 5, the edge of the transparent electrode layer 9, the edge of the p-type GaN layer 7, and the edge of the light emitting layer 5 are formed to coincide with one another, whereby it becomes possible to enlarge the area of the light emitting region and to improve the light output. Moreover, the manufacturing process can be simplified and the cost can be also reduced by continuously etching the transparent electrode layer 9, the p-type GaN layer 7, and the light emitting layer 5.

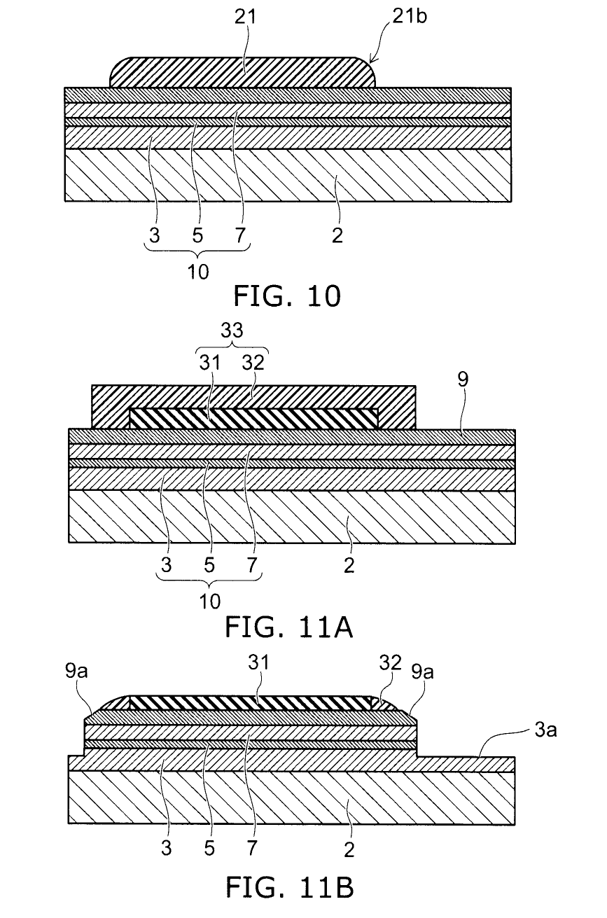

In contrast, in the manufacturing process of the semiconductor light emitting device 100, a resist film may be used for the etching mask 21 of the transparent electrode layer 9, the p-type GaN layer 7, and the light emitting layer 5, although the example is shown to use a SiO₂ film, Then, as shown in FIG. 10, the etching mask 21 may be deformed so that the thickness of the resist film becomes smaller in the direction from the center side to the edge side. For example, the resist film can be deformed into the shape as shown by 21b in FIG. 10, by carrying out a thermal treatment at a temperature higher than its softening temperature.

### Second Embodiment

FIGS. 11A and 11B are schematic views showing a method for manufacturing a semiconductor light emitting device according to the second embodiment.

As shown in FIG. 11A, the transparent electrode layer 9, the p-type GaN layer 7, and the light emitting layer 5 are etched, by using an etching mask 33 in which a SiO₂ film 31 and a resist film 32 are stacked on the transparent electrode layer 9. As shown in the figure, the resist film 32 is formed so as to cover the entire surface of the SiO₂ film 31.

FIG. 11B is a schematic view showing a partial cross section of a wafer that is dry-etched by using the etching mask 33. As shown in FIG. 11B, the transparent electrode layer 9, the p-type GaN layer 7, and the light emitting layer 5 are etched, and thus the surface 3a of the n-type GaN layer 3 is exposed. Then, the region 9a along the edge of the transparent electrode layer 9 is formed. When the resist film 32 is all etched, the SiO₂ film 31 remains on the surface of the transparent electrode layer 9. That is, it may be possible to prevent the over-etching of the transparent electrode layer 9, due to the stacking structure of the SiO₂ film 31 and the resist film 32.

### Third Embodiment

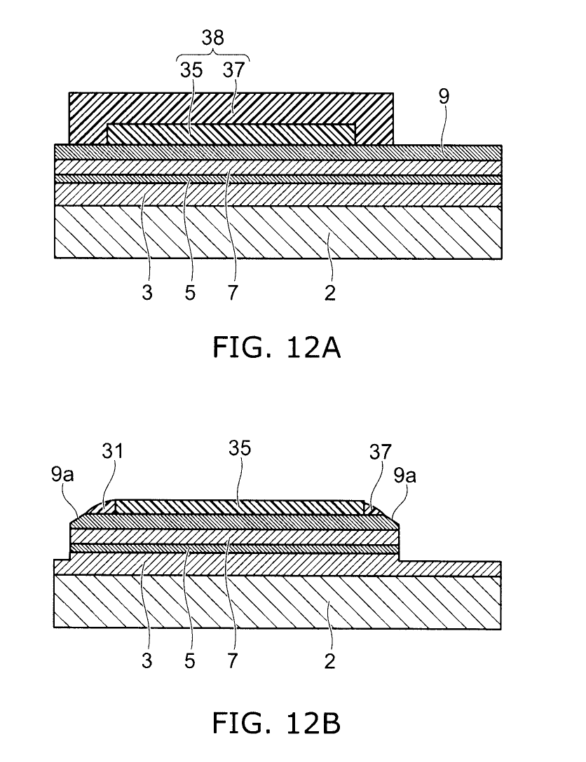

FIGS. 12A and 12B are schematic views showing a method for manufacturing a semiconductor light emitting device according to the third embodiment. As shown in FIG. 12A, in the method for manufacturing according to the embodiment, an etching mask 38 includes a resist film 35 and a resist film 37 stacked on the transparent electrode layer 9. The resist film 37 is provided so as to cover the entire surface of the resist film 35.

FIG. 12B is a schematic view illustrating a partial cross section of a wafer that is dry-etched by using the etching mask 38. By stacking the resist film 35 and the resist film 37, after the resist film 37 is etched, the resist film 35 remains on the surface of the transparent electrode layer 9 to thereby prevent the overetching. For example, a material having an etching rate lower than an etching rate of the resist film 37 is used for the resist film 35.

### Fourth Embodiment

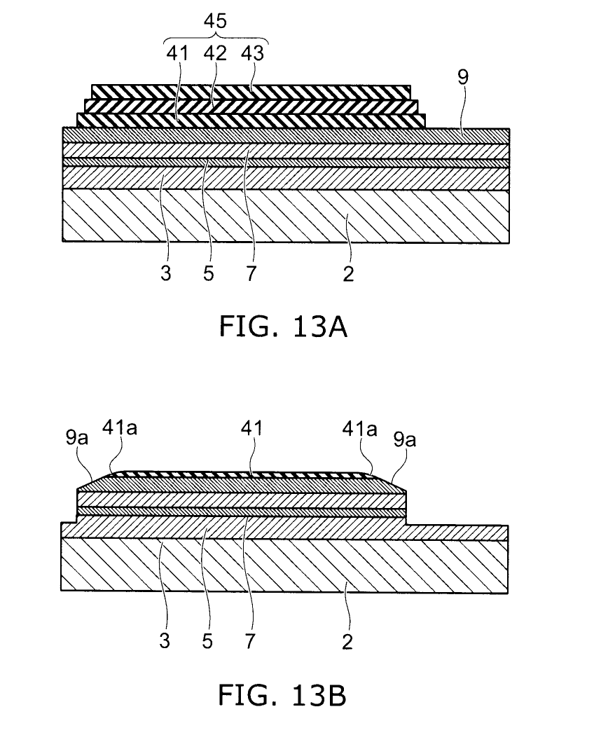

FIGS. 13A and 13B are schematic views showing a method for manufacturing a semiconductor light emitting device according to the fourth embodiment. As shown in FIG. 13A, in the method for manufacturing according to the embodiment, the transparent electrode layer 9, the p-type GaN layer 7, and the light emitting layer 5 are etched by using a three-layer etching mask 45 including a SiO₂ film 41, a SiO₂ film 42 and a SiO₂ film 43, for example. As shown in FIG. 13A, the edge of the SiO₂ film 42 is formed so as to retreat inside the edge of the SiO₂ film 41, the SiO₂ film 42 is formed in a state in which the edge of the SiO₂ film 43 retreats inside the edge of the SiO₂ film 42.

FIG. 11B is a schematic view showing a partial cross section of a wafer that is dry-etched by using the etching mask 45. As shown in FIG. 11B, after the transparent electrode layer 9, the p-type GaN layer 7, and the light emitting layer 5 are etched, the etching is carried out so that at least the SiO₂ film 41 remains on the transparent electrode layer 9. Thereby, it is possible to prevent the overetching of the transparent electrode layer 9. Furthermore, by adjusting the retreat widths of the SiO₂ films 42 and 43, it is possible to control the shape of the region 9a formed along the edge of the transparent electrode layer 9.

Moreover, an etching mask of a three-layer structure in which a resist film is used may be substituted for the SiO₂ films 41 to 43. For example, a three-layer structure of positive resist/negative resist/positive resist may be used.

The above-described embodiment are not limited to a semiconductor light emitting device using a GaN-based nitride semiconductor, but can be applied to a semiconductor light emitting device having other nitride semiconductors or an AlGaInP-based semiconductor as material.

Also, in the specification of this application, “nitride semiconductor” includes a III-V compound semiconductor of BₓIn_{y}Al_{z}Ga_{1-x-y-z}N (0≦x≦1, 0≦y≦1, 0≦z≦1, and 0≦x+y+z≦1), and furthermore, a mixed crystal containing phosphorus (P), arsenic (As), or the like, in addition to nitrogen (N) is also contained as group V element. Moreover, the “nitride semiconductor” includes also those which further contain various elements added in order to control various physical properties such as a conductivity type and the like, and those which further contain various elements to be unintentionally contained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting device comprising:
a stacked body including a first semiconductor layer of a first conductivity type, a second semiconductor layer of a second conductivity type, and a light emitting layer provided between the first semiconductor layer and the second semiconductor layer;
a transparent electrode layer, provided on a surface of the second semiconductor layer, transmitting light emitted from the light emitting layer;
a first electrode electrically connected to the transparent electrode layer; and
a second electrode electrically connected to the first semiconductor layer,
and a region provided along an edge of the transparent electrode layer with a part of the transparent electrode layer, the region having a thickness smaller on the edge side than a thickness on a central side.

2. The device according to claim 1, wherein the edge of the transparent electrode layer contacts a side face of the second semiconductor layer provided by an etching in a direction from a surface of the transparent electrode layer to the first semiconductor layer.

3. The device according to claim 1, wherein the edge of the transparent electrode layer coincides with an edge of the second semiconductor layer.

4. The device according to claim 1, wherein a width of the region from the central side to the edge in a direction along the surface of the second semiconductor layer is narrower than a thickness of the stacked body in a stacking direction in the region along the edge of the transparent electrode layer.

5. The device according to claim 1, wherein a width of the region from the central side to the edge in a direction along the surface of the second semiconductor layer is narrower than a thickness of the second semiconductor layer in the region along the edge of the transparent electrode layer.

6. The device according to claim 1, wherein the transparent electrode layer includes a conductive oxide film.

7. The device according to claim 1, wherein the transparent electrode layer contains one of ITO and ZnO.

8. The device according to claim 1, wherein the region along the edge of the transparent electrode layer is provided with a tapered shape that becomes thinner from the central side toward the edge.

9. The device according to claim 1, wherein each of the first semiconductor layer, the second semiconductor layer, and the light emitting layer includes a GaN-based nitride semiconductor.

10. The device according to claim 1, wherein the first semiconductor layer, the second semiconductor layer, and the light emitting layer are provided on a sapphire substrate.

11. The device according to claim 1, wherein each of the first semiconductor layer, the second semiconductor layer, and the light emitting layer includes an AlGaInP-based semiconductor.

12. A method for manufacturing a semiconductor light emitting device, the method comprising:
forming a first semiconductor layer of a first conductivity type, a light emitting layer, and a second semiconductor layer of a second conductivity type on a substrate;
forming, on the second semiconductor layer, a transparent electrode layer transmitting light emitted from the light emitting layer; and
continuously etching the transparent electrode layer, the second semiconductor layer, and the light emitting layer in a direction from a surface of the transparent electrode layer to the first semiconductor layer,
and the transparent electrode layer including a part having a thickness smaller on the edge side than a thickness on a central side, the part of the transparent electrode layer being provided along an edge formed by the etching.

13. The method according to claim 12, wherein an edge shape of a mask used for etching the transparent electrode layer, the second semiconductor layer, and the light emitting layer is transferred into the part along the edge of the transparent electrode layer.

14. The method according to claim 12, wherein an RIE (Reactive Ion Etching) method is used for etching the transparent electrode layer, the second semiconductor layer, and the light emitting layer.

15. The method according to claim 14, wherein the transparent electrode layer, the second semiconductor layer, and the light emitting layer are etched under a condition in which etching in the direction from the transparent electrode layer toward the first semiconductor layer is dominant.

16. The method according to claim 12, wherein a mask used for etching the transparent electrode layer, the second semiconductor layer, and the light emitting layer includes a silicon oxide film (SiO₂).

17. The method according to claim 12, wherein a mask used for etching the transparent electrode layer, the second semiconductor layer, and the light emitting layer is a resist film treated at a temperature higher than a softening temperature.

18. The method according to claim 12, wherein a mask used for etching the transparent electrode layer, the second semiconductor layer, and the light emitting layer includes a silicon oxide film (SiO₂) and a resist film.

19. The method according to claim 12, wherein a mask used for etching the transparent electrode layer, the second semiconductor layer, and the light emitting layer includes a plurality of resist films.

20. The method according to claim 12, wherein a mask used for etching the transparent electrode layer, the second semiconductor layer, and the light emitting layer includes a plurality of silicon oxide films (SiO₂).
